(19) United States
(12) Patent Application Publication
(10) Pub. No.: US 2025/0026007 A1
(43) Pub. Date: Jan. 23, 2025

(54) METHOD AND SYSTEM FOR DETERMINING A JOINT IN A VIRTUAL KINEMATIC DEVICE

(71) Applicant: Siemens Industry Software Ltd., Tel Aviv (IL)

(72) Inventors: Moshe Hazan, Elad (IL); Shahar Zuler, Rosh Haayin (IL); Albert Harounian, Ramat Gan (IL); Gil Chen, Bnei Zion (IL); Diana Gospodinova, Sofia (BG)

(21) Appl. No.: 18/687,949

(22) PCT Filed: Aug. 30, 2021
(86) PCT No.: PCT/IB2021/057901

§ 371 Date: Feb. 29, 2024

(51) Int. Cl. B25J 9/16; B25J 9/00

(52) U.S. Cl. CPC B25J 9/1605; B25J 9/003; B25J 9/1664

(57) ABSTRACT

Systems and a method for determining a joint in a virtual kinematic device. Input data are received which contain data on two point cloud representations of two given links of a given virtual kinematic device and data on the specific joint type associated with the two links. A specific joint descriptor analyzer is applied to the input data. The specific joint descriptor analyzer is modeled with a function trained by a machine learning (ML) algorithm and the specific joint descriptor analyzer generates output data. The output data contains specific joint descriptor data for determining the mutual motion capabilities of the specific joint type associated with the two given links. From the output data, at least one joint is determined in the virtual kinematic device.

### TECHNICAL FIELD

The present disclosure is directed, in general, to computer-aided design, visualization, and manufacturing (“CAD”) systems, product lifecycle management (“PLM”) systems, product data management (“PDM”) systems, production environment simulation, and similar systems, that manage data for products and other items (collectively, “Product Data Management” systems or PDM systems). More specifically, the disclosure is directed to production environment simulation.

### BACKGROUND OF THE DISCLOSURE

In manufacturing plant design, three-dimensional (“3D”) digital models of manufacturing assets are used for a variety of manufacturing planning purposes. Examples of such usages includes, but are not limited by, manufacturing process analysis, manufacturing process simulation, equipment collision checks and virtual commissioning.

As used herein the terms manufacturing assets and devices denote any resource, machinery, part and/or any other object present in the manufacturing lines.

Manufacturing process planners use digital solutions to plan, validate and optimize production lines before building the lines, to minimize errors and shorten commissioning time.

Process planners are typically required during the phase of 3D digital modeling of the assets of the plant lines.

While digitally planning the production processes of manufacturing lines, the manufacturing simulation planners need to insert into the virtual scene a large variety of devices that are part of the production lines. Examples of plant devices include, but are not limited by, industrial robots and their tools, transportation assets like e.g. conveyors, turn tables, safety assets like e.g. fences, gates, automation assets like e.g. clamps, grippers, fixtures that grasp parts and more.

While simulating the process, many of these elements have a kinematic definition that controls the motion of these elements.

Some of these devices are kinematic devices with one or more kinematic capabilities which require a kinematic definition via kinematic descriptors of the kinematic chains. The kinematic device definitions enable to simulate, in the virtual environment, the kinematic motions of the kinematic device chains. An example of kinematic device is a clamp which opens its fingers before grasping a part and which closes such fingers for having a stable grasp of the part. For a simple clamp with two rigid fingers, the kinematics definition typically consists in assigning two links descriptors to the two fingers and a joint descriptor to their mutual rotation axis positioned through their links node as shown in FIG. 2D which schematically illustrates a drawing of a virtual kinematic clamp 252 with a rotational axis j1 and the corresponding virtual kinematic editor screen 254 with descriptors lnk1, lnk2, j1 of the clamp 252.

As known in the art of kinematic chain definition, a joint is defined as a connection between two or more links at their nodes, which allows some motion, or potential motion, between the connected links. The following presents simplified definitions of terminology in order to provide a basic understanding of some aspects described herein. As used herein, a kinematic device may denote a device having a plurality of kinematic capabilities defined by a chain, whereby each kinematic capability is defined by descriptors describing a set of links and a set of joints of the chain. In other words, a kinematics descriptor may provide a full or a partial kinematic definition of a kinematic capability of a kinematic device. As used herein a kinematic descriptor may denote a link identifier, a link type, a joint identifier, a joint type, a joint descriptor etc. A link identifier identifies a link. For example, in the gripper 202 of FIG. 2B there are three links lnk1, lnk2, lnk3 and two translational joints j1, j2, where joint j1 is the joint connecting the two links lnk1, lnk3 and where joint j2 is the joint connecting the two links link1, link2.

Although there are many ready 3D device libraries that can be used by planners, most of these 3D models lack a kinematics definition and their virtual representations are hereby denoted with the term “virtual dummy devices” or “dummy devices”. Therefore, simulation planners are usually required to manually define the kinematics of these 3D dummy device models, a task which is time consuming, especially with manufacturing plants with a large number of kinematic devices like for example with automotive plants.

Typically, manufacturing process planners are solving this problem by assigning simulation engineers to maintain the resource library, so they manually model the required kinematics for each one of these resources. The experience of the simulation engineers help them to understand how the kinematics should be created and added to the devices. They are required to identify the links and joints of the devices and define them. This manual process consumes precious time of experienced users.

FIG. 2A schematically illustrates a block diagram of a typical manual analysis of the kinematics capability of a virtual gripper model (Prior Art).

The simulation engineer 203 analyzes the kinematic capability of a CAD model of a dummy gripper 201, whereby the dummy virtual device is lacking a kinematic definition. She loads into the virtual environment the gripper dummy model 201 and with her analysis she identifies the three links lnk1, lnk2, lnk3 and the two translational joints jnt1, jnt2 of the gripper's chain in order to build a kinematic gripper model 203 via a kinematics editor screen 204 comprising kinematic descriptors of the links lnk1, lnk2, link3 and the two joints j1,j2 which are the two connectors between link lnk1 and the other two links lnk3, link2. FIG. 2B schematically illustrates a zoomed drawing of the virtual kinematic gripper 202 of FIG. 2A and FIG. 2C schematically illustrates a zoomed drawing of the virtual kinematic editor screen 204 of FIG. 2A. In this example, it is shown a specific example of kinematic chain, the skilled in the art knows that there are kinematic devices having different chains, with different numbers of links and different numbers and types of joints. Examples of kinematic joint types include, but are not limited by, translational joints—also called prismatic, rotational joints—also called revolute, spherical joints, cylindrical joints, helical joints and planar joints. Each type of joint is characterized by a joint descriptor for describing the mutual motion between the connected links, for examples in case of translational joint the joint descriptor contains the description of the direction of the translation motion and in case of rotational joint the joint descriptor describes the rotational axis.

The dummy gripper model 201—i.e. the model without kinematics—may be defined in a CAD file format, in a mesh file format and/or via a 3D scan. The gripper model 202 with kinematics descriptors may be preferably defined in a file format allowing CAD geometry together with kinematics definition as for example jt. format files with both geometry and kinematics (which are usually stored in a cojt. folder) for the Process Simulate platform, or for example .prt format files for the NX platform, or any other kinematics object file formats which can be used by an industrial motion simulation software, e.g. a Computer Aided Robotic (“CAR”) tool like for example Process Simulate of the Siemens Digital Industries Software group.

As above explained, creating and maintaining definitions of kinematics capabilities and corresponding links and joints descriptors of the kinematic chains for a large variety of kinematic devices is a manual, tedious, repetitive and time-consuming task and requires the skills of experienced users.

Patent application PCT/IB2021/055391 teaches an inventive technique for automatically identifying kinematic capabilities in virtual devices.

Patent application PCT/IB2021/056734 teaches an inventive technique for automatically identifying kinematic capabilities in virtual devices. In embodiments, the links of a kinematic device are determined.

Once a pair of kinematic links in a kinematic devices are known, the joint connecting the link pair has then still to be determined by the simulation engineer in a manual and time consuming manner.

Improved and automatic techniques for determining a joint in a virtual kinematic device are therefore desirable.

### SUMMARY OF THE DISCLOSURE

Various disclosed embodiments include methods, systems, and computer readable mediums for determining a joint in a virtual kinematic device. A method includes receiving input data; wherein the input data comprise data on two point cloud representations of two given links of a given virtual kinematic device. The method further includes applying a joint type analyzer to the input data; wherein the joint type analyzer is modeled with a function trained by a Machine Learning (“ML”) algorithm and the joint type analyzer generates intermediate data. The method further includes providing intermediate data; wherein the intermediate data comprises data for selecting a specific joint type associated to the two given links. The method further includes applying the selected specific joint descriptor analyzer to the input data; wherein the specific joint descriptor analyzer is modeled with a function trained by a ML algorithm and the specific joint descriptor analyzer generates output data. The method further includes providing the output data; wherein the output data comprises specific joint descriptor data for determining the mutual motion capabilities of the specific joint type associated to the two given links. The method further includes determining from the output data at least one joint in the virtual kinematic device.

Various disclosed embodiments include methods, systems, and computer readable mediums for determining a joint in a virtual kinematic device. A method includes receiving input data; wherein the input data comprise data on two point cloud representations of two given links of a given virtual kinematic device and data on the specific joint type associated to the two links. The method further includes applying a specific joint descriptor analyzer to the input data; wherein the specific joint descriptor analyzer is modeled with a function trained by a ML algorithm and the specific joint descriptor analyzer generates output data. The method further includes providing the output data; wherein the output data comprises specific joint descriptor data for determining the mutual motion capabilities of the specific joint type associated to the two given links The method further includes determining from the output data at least one joint in the virtual kinematic device.

Various disclosed embodiments include methods, systems, and computer readable mediums for providing a trained function for identifying a joint type in a virtual kinematic device. A method includes receiving input training data; wherein the input data comprise data on a plurality of two point cloud representations of two given links of a plurality of virtual kinematic devices. The method further includes receiving output training data; wherein the output training data comprise, for each of the plurality of two point cloud link representations, data for determining the specific joint type associated to the two given links; wherein the output training data is related to the input training data. The method further includes training a function based on the input training data and the output training data via a ML algorithm. The method further includes providing the training function for modeling a joint type analyzer.

Various disclosed embodiments include methods, systems, and computer readable mediums for providing a trained function for identifying a joint descriptor in a virtual kinematic device. A method includes receiving input training data; wherein the input data comprise data on a plurality of two point cloud representations of two given links of a plurality of virtual kinematic devices. The method further includes receiving output training data; wherein the output training data comprises, for each of the plurality of two point cloud link representations, specific joint descriptor data for determining the mutual motion capabilities of the specific joint type associated to the two given links. The method further includes training a function based on the input training data and the output training data via a ML algorithm. The method further includes providing the trained function for identifying a joint descriptor herein called joint descriptor analyzer.

The foregoing has outlined rather broadly the features and technical advantages of the present disclosure so that those skilled in the art may better understand the detailed description that follows. Additional features and advantages of the disclosure will be described hereinafter that form the subject of the claims. Those skilled in the art will appreciate that they may readily use the conception and the specific embodiment disclosed as a basis for modifying or designing other structures for carrying out the same purposes of the present disclosure. Those skilled in the art will also realize that such equivalent constructions do not depart from the spirit and scope of the disclosure in its broadest form.

Before undertaking the DETAILED DESCRIPTION below, it may be advantageous to set forth definitions of certain words or phrases used throughout this patent document: the terms “include” and “comprise,” as well as derivatives thereof, mean inclusion without limitation; the term “or” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, whether such a device is implemented in hardware, firmware, software or some combination of at least two of the same. It should be noted that the functionality associated with any particular controller may be centralized or distributed, whether locally or remotely. Definitions for certain words and phrases are provided throughout this patent document, and those of ordinary skill in the art will understand that such definitions apply in many, if not most, instances to prior as well as future uses of such defined words and phrases. While some terms may include a wide variety of embodiments, the appended claims may expressly limit these terms to specific embodiments.

### BRIEF DESCRIPTION OF THE DRAWINGS

For a more complete understanding of the present disclosure, and the advantages thereof, reference is now made to the following descriptions taken in conjunction with the accompanying drawings, wherein like numbers designate like objects, and in which:

FIG. 1 illustrates a block diagram of a data processing system in which an embodiment can be implemented.

FIG. 2A schematically illustrates a block diagram of a typical manual analysis of the kinematics capability of a virtual gripper (Prior Art).

FIG. 2B schematically illustrates a zoomed drawing of the virtual kinematic gripper 202 of FIG. 2A.

FIG. 2C schematically illustrates a zoomed drawing of the virtual kinematic editor screen 204 of FIG. 2A.

FIG. 2D schematically illustrates a drawing of a virtual kinematic clamp and its corresponding virtual kinematic editor screen.

FIG. 3A schematically illustrates a block diagram for training a function with a ML algorithm for determining a joint in a virtual kinematic device in accordance with disclosed embodiments.

FIG. 3B schematically illustrates exemplary input training data for training a function with a ML algorithm in accordance with disclosed embodiments.

FIG. 3C schematically illustrates exemplary output training data for training a function with a ML algorithm in accordance with disclosed embodiments.

FIG. 4 schematically illustrates a block diagram for determining a joint in a virtual kinematic device in accordance with disclosed embodiments.

FIG. 5 schematically illustrates a block diagram for determining a joint in a virtual kinematic device in accordance with disclosed embodiments.

FIG. 6 illustrates a flowchart for identifying a kinematic capability in a virtual kinematic device in accordance with disclosed embodiments.

### DETAILED DESCRIPTION

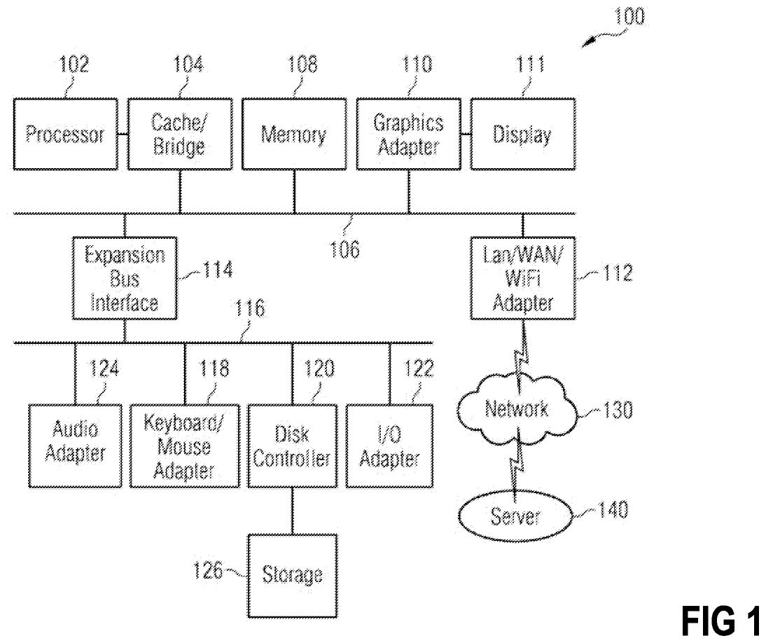

FIGS. 1 through 6, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged device. The numerous innovative teachings of the present application will be described with reference to exemplary non-limiting embodiments.

Furthermore, in the following the solution according to the embodiments is described with respect to methods and systems for determining a joint in a virtual kinematic device as well as with respect to methods and systems for providing a trained function for determining a joint in a virtual kinematic device.

Features, advantages, or alternative embodiments herein can be assigned to the other claimed objects and vice versa.

In other words, claims for methods and systems for providing a trained function for determining a joint in a virtual kinematic device can be improved with features described or claimed in context of the methods and systems for determining a joint in a virtual kinematic device and vice versa. In particular, the trained function of the methods and systems for determining a joint in a virtual kinematic device can be adapted by the methods and systems for determining a joint in a virtual kinematic device. Furthermore, the input data can comprise advantageous features and embodiments of the training input data, and vice versa. Furthermore, the output data can comprise advantageous features and embodiments of the output training data, and vice versa.

Previous techniques did not enable efficient kinematics capability identification in a virtual kinematic device. The embodiments disclosed herein provide numerous technical benefits, including but not limited to the following examples.

Embodiments enable to automatically identify and define kinematic capabilities of virtual kinematic devices.

Embodiments enable to identify and define the kinematic capabilities of virtual kinematic devices in a fast and efficient manner.

Embodiments minimizes the need of trained users for identifying kinematic capabilities of kinematic devices and reduce engineering time. Embodiments minimizes the quantity of “human errors” in defining the kinematic capabilities of virtual kinematic devices.

Embodiments may advantageously be used for a large variety of different types of kinematics devices.

Embodiments are based on a 3D dimensional analysis of the virtual device.

Embodiments enable an in-depth analysis of the virtual device via the point cloud inputs enabling to cover all device entities, even the hidden ones.

Embodiments enable to detect, within kinematic devices, the types of joints and their kinematic descriptors like for example direction and/or location.

Embodiments enable to automatically analyze the joint(s) present in a virtual kinematic device via Artificial Intelligence and via received point cloud data.

Given a pair of point cloud links of a device, embodiments enable to identify the presence of a joint connecting the link pair and its joint type.

Given a pair of point cloud links and the corresponding joint type within a kinematic device, embodiments enable to determine the joint descriptor, e.g. a direction and/or a location and, in case of an helical joint type, its helical pitch.

FIG. 1 illustrates a block diagram of a data processing system 100 in which an embodiment can be implemented, for example as a PDM system particularly configured by software or otherwise to perform the processes as described herein, and in particular as each one of a plurality of interconnected and communicating systems as described herein. The data processing system 100 illustrated can include a processor 102 connected to a level two cache/bridge 104, which is connected in turn to a local system bus 106. Local system bus 106 may be, for example, a peripheral component interconnect (PCI) architecture bus. Also connected to local system bus in the illustrated example are a main memory 108 and a graphics adapter 110. The graphics adapter 110 may be connected to display 111.

Other peripherals, such as local area network (LAN)/Wide Area Network/Wireless (e.g. WiFi) adapter 112, may also be connected to local system bus 106. Expansion bus interface 114 connects local system bus 106 to input/output (I/O) bus 116. I/O bus 116 is connected to keyboard/mouse adapter 118, disk controller 120, and I/O adapter 122. Disk controller 120 can be connected to a storage 126, which can be any suitable machine usable or machine readable storage medium, including but are not limited to nonvolatile, hard-coded type mediums such as read only memories (ROMs) or erasable, electrically programmable read only memories (EEPROMs), magnetic tape storage, and user-recordable type mediums such as floppy disks, hard disk drives and compact disk read only memories (CD-ROMs) or digital versatile disks (DVDs), and other known optical, electrical, or magnetic storage devices.

Also connected to I/O bus 116 in the example shown is audio adapter 124, to which speakers (not shown) may be connected for playing sounds. Keyboard/mouse adapter 118 provides a connection for a pointing device (not shown), such as a mouse, trackball, trackpointer, touchscreen, etc.

Those of ordinary skill in the art will appreciate that the hardware illustrated in FIG. 1 may vary for particular implementations. For example, other peripheral devices, such as an optical disk drive and the like, also may be used in addition or in place of the hardware illustrated. The illustrated example is provided for the purpose of explanation only and is not meant to imply architectural limitations with respect to the present disclosure.

A data processing system in accordance with an embodiment of the present disclosure can include an operating system employing a graphical user interface. The operating system permits multiple display windows to be presented in the graphical user interface simultaneously, with each display window providing an interface to a different application or to a different instance of the same application. A cursor in the graphical user interface may be manipulated by a user through the pointing device. The position of the cursor may be changed and/or an event, such as clicking a mouse button, generated to actuate a desired response.

One of various commercial operating systems, such as a version of Microsoft Windows™, a product of Microsoft Corporation located in Redmond, Wash. may be employed if suitably modified. The operating system is modified or created in accordance with the present disclosure as described.

LAN/WAN/Wireless adapter 112 can be connected to a network 130 (not a part of data processing system 100), which can be any public or private data processing system network or combination of networks, as known to those of skill in the art, including the Internet. Data processing system 100 can communicate over network 130 with server system 140, which is also not part of data processing system 100, but can be implemented, for example, as a separate data processing system 100.

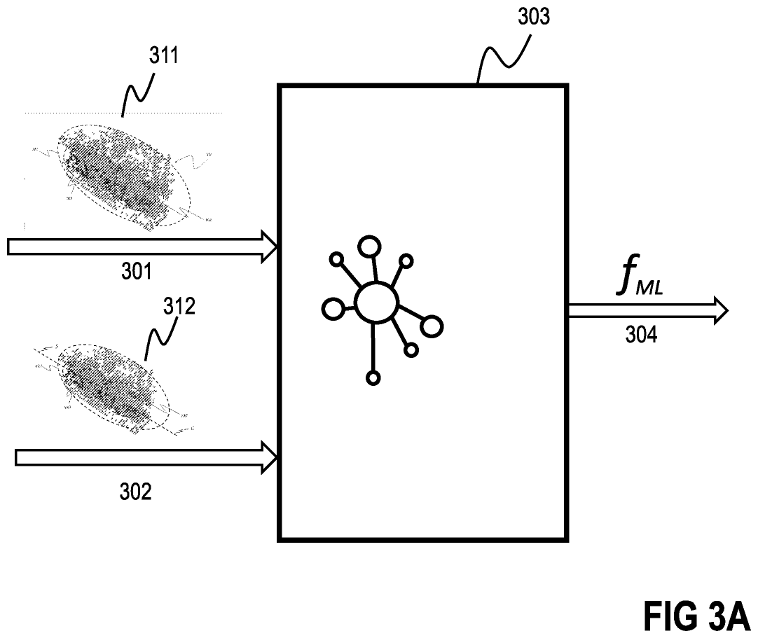

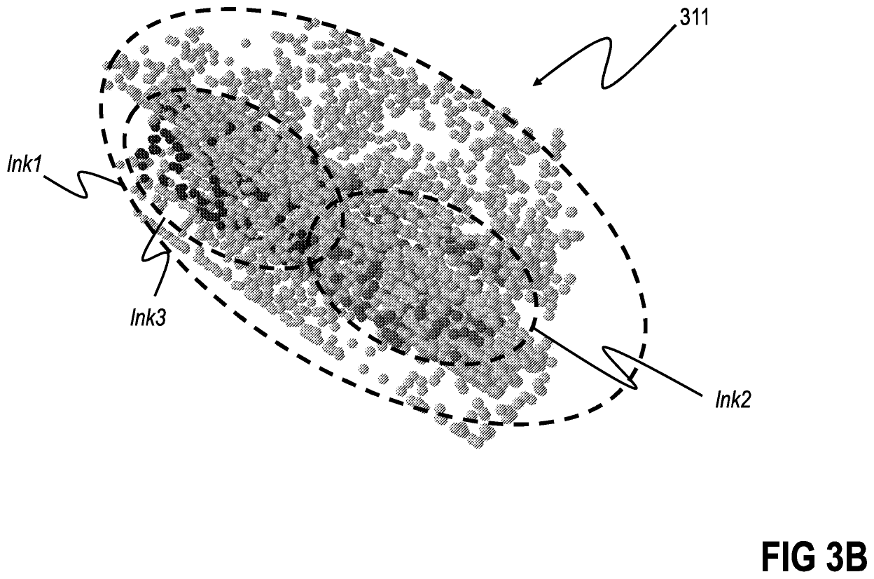

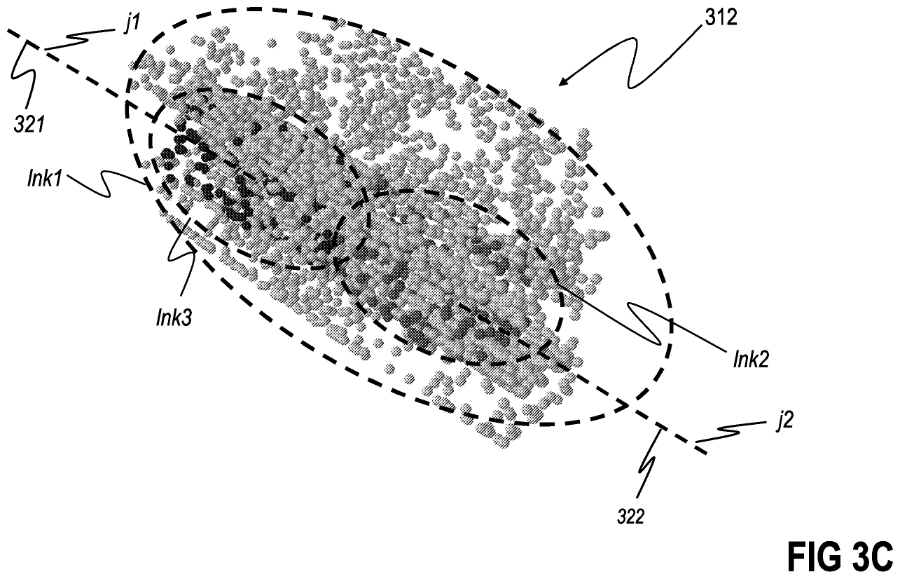

FIG. 3A schematically illustrates a block diagram for training a function with a ML algorithm for determining a joint in a virtual kinematic device in accordance with disclosed embodiments. In embodiments, the joint type may be already given, and the joint descriptor is the output training data 302 of the ML algorithm.

In embodiments, inputs training data 301 comprise data on two points cloud representations of two given links 311 of a given virtual kinematic device. In embodiments, the point cloud representation of the two links may be received from different sources. Examples of sources include, but are not limited by, tagging the links of point clouds representations from received 3D device models, manually or via meta-data extractions and outcomes from the kinematic analyzer taught in patent application PCT/IB2021/056734.

As used herein the terms “link point cloud” or “point cloud link” denote a point cloud representation of a link of a virtual device and the term link 3D model denotes other 3D model representations like for example CAD models, mesh models, 3D scans etc. In embodiments, point cloud links are received directly in other embodiments the point cloud devices are extracted from received 3D device models.

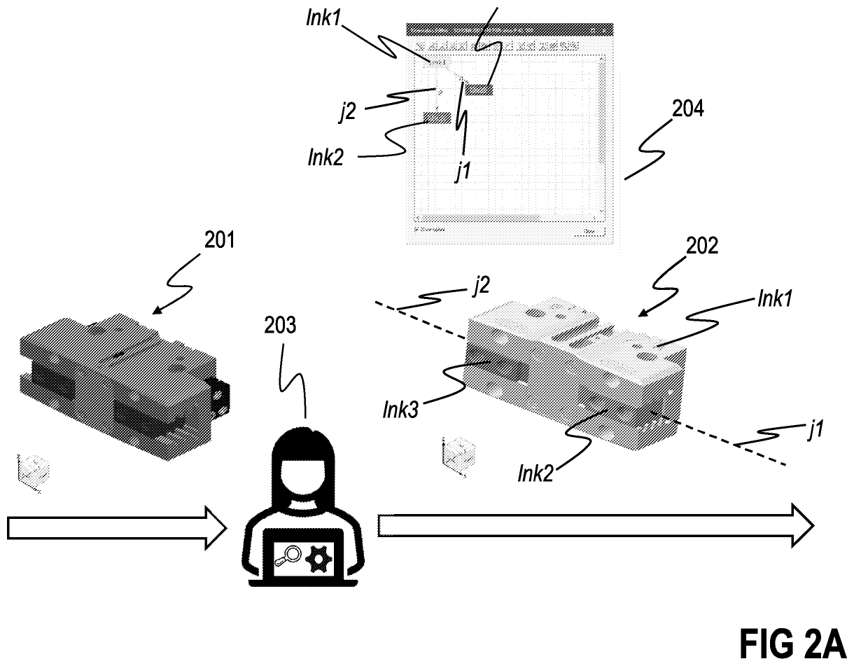

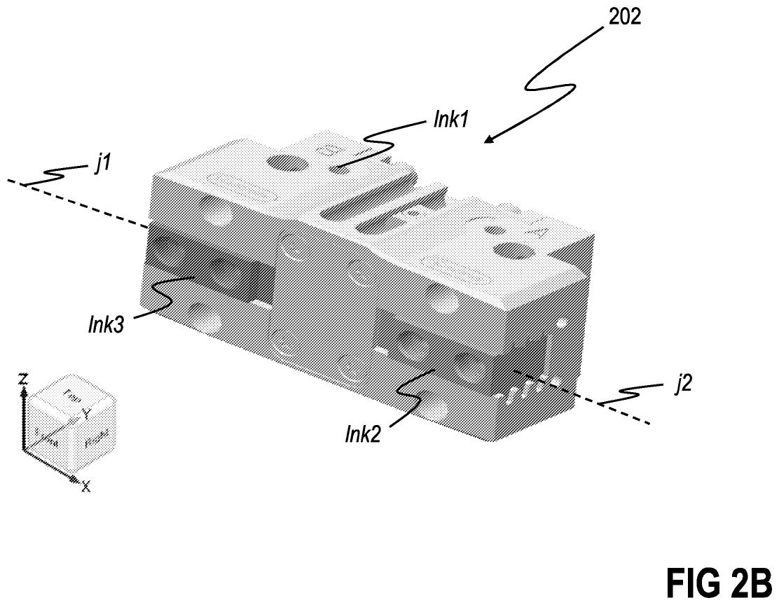

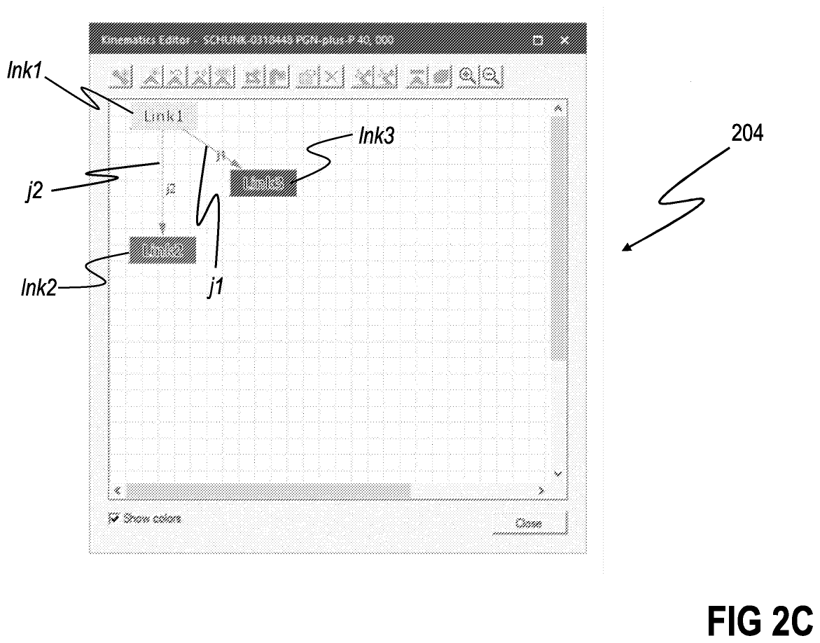

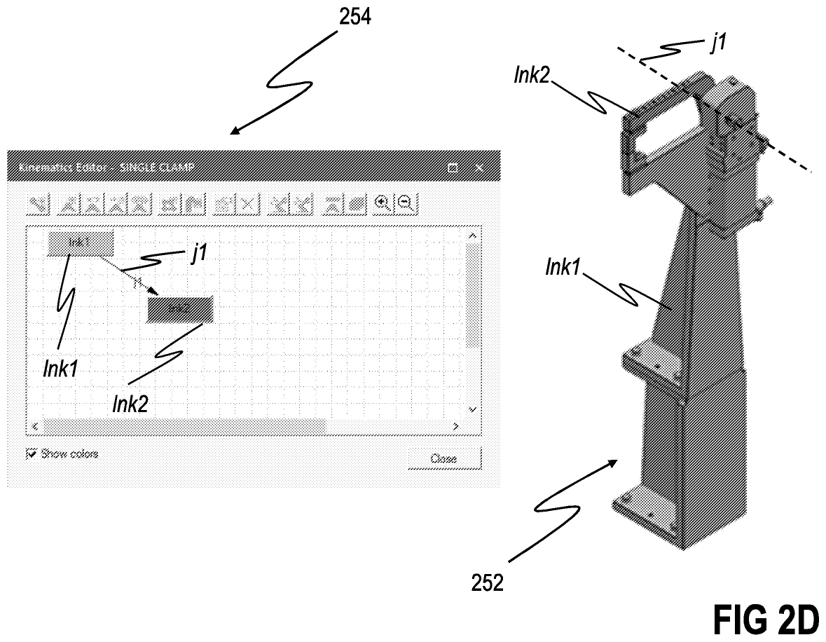

FIGS. 3B schematically illustrates exemplary input training data for training a function with a ML algorithm in accordance with disclosed embodiments. In FIG. 3B are shown point cloud links of a virtual device 311. In particular, the point cloud links lnk1, lnk2, lnk3 correspond to the three links of the virtual gripper shown in FIG. 2A. For explanatory purposes, in FIG. 3B, three different links lnk1, lnk2, lnk3 are shown. In embodiments, the point cloud links of the input training data are given in pairs, e.g. pair link lnk1, lnk3 and pair link lnk1, lnk2.

The link cloud points 311 are usually defined with a list of link points including each 3D coordinates and, optionally, other information such as colors, surface normals, entity identifiers and other features. For example, the point cloud is defined by a list of points List <Point> where each point contains X,Y,Z and optionally other information such as colors, surface normals, entity identifiers and other features.

FIGS. 3C schematically illustrates exemplary output training data for training a function with a ML algorithm in accordance with disclosed embodiments.

The output training data 302 are obtained by getting, for each point cloud link pair, types and descriptors of the joints j1, j2, connecting respectively pair link lnk1, lnk3 and pair link lnk1, link2 in the kinematic device. For example, it is provided the joint type (if any) and its descriptor. In the exemplary embodiments of FIGS. 3A-C, it is already given that the joints j1, j2 to be determined are of translational type and the trained module provides as output data the joint descriptors of the joint directions.

In embodiments, the output training data may automatically be generated as labeled training dataset departing from the kinematic file of the device model or from a metadata file associated to the dummy device. In other embodiments, output training data may be manually generated by defining and labeling each joint(s) with descriptor(s). In other embodiments, a mix of automatic and manual labeled dataset may advantageously be used.

In FIG. 3C, it is shown the point cloud link pairs with the corresponding joints j1, j2 312. The labeled output training data are shown for illustration purposes by marking the descriptors 321, 322 of the joint directions.

Such link descriptors 321, 322 can be for example provided for training purposes by extracting data from the metadata of the device kinematic file or by analyzing the metadata with names and tags of the dummy device file.

Embodiments for generating output training data 302 may comprise one or more of the following actions:
loading a set of virtual devices with already labeled joints for example from already existing modeled kinematics devices;
loading a set of virtual dummy devices into a virtual tool and generating joint descriptors from the point cloud links extracted in each dummy device.

Examples of labeling sources include, but are not limited by, language topology on the device entities, metadata on the device e.g. from manuals, work instructions, machinal drawings, existing kinematic data and/or manual labeling etc. In embodiments, naming conventions provided by the device vendors can advantageously be used to define which entity relates to each link lnk1, lnk2, lnk3 and which entity pair to which joint j1, j2 this naming convention can be used for libraries which lack their own ones.

From the labeled devices, point cloud links pair with labeled joint descriptors are extracted. In order to improve performances, the point cloud device 311 may preferably be down sampled. In FIG. 3C, the joint descriptors of the two joints j1, j2 are the descriptors defining the directions of the translational axes 321, 322. In embodiments, the direction of one translational axis may be given as 3D coordinates of a unit vector.

In embodiments of the ML training phase, the input training data 301 for training the neural network are the point cloud link pairs and the output training data 302 are the corresponding labeled data/metadata of the joints, e.g. the determined descriptors associated to each link pair.

In embodiments, the result of the training process 303 is a trained neural network 304 capable of automatically determining the joint descriptor from a given pair of point cloud links of a given joint type in a virtual kinematic device.

In embodiments, the trained neural network herein called “joint descriptor analyzer” is capable of determining a joint descriptor from a corresponding pair of point cloud links of a given joint type.

In embodiments, the joint descriptor analyzer is a module where input data include points cloud data of a link pair connected by a joint of a given type and where the output data are data for defining the joint, e.g. joint direction and/or location depending on the joint type.

In embodiments, the given type of joint is received by a user or is automatically determined from the metadata. In other embodiments, the given join type is determined via a ML trained module.

In embodiments, the training of the ML algorithm requires a labeled training dataset, a dataset for training the ML model as to be able to recognize the joints from the pairs of point cloud links.

In embodiments, the training data set with labels comprise point cloud data of link pairs connected by joint of given types and corresponding joint descriptors. In embodiments, the labels are based on manual tagging of CAD files and prior existing data.

In embodiments, training data augmentation may be obtained by moving each joint, rotate and\or mirror the entire point cloud, and random down sampling of the point cloud. Advantageously, the size of the data set is increased.

In embodiments, the point cloud links may optionally be down sampled for performance optimizations. For example, assume there are circa 10 k points in a single point cloud joint, although the whole 10 k point cloud can be used directly, much of the points may not add much more information to the ML model, therefore, one can down sample the point cloud to circa 1 k points with down sampling techniques and/or other augmentation techniques. Advantageously, a large dataset training can be done faster.

In other example embodiments, other types of additional information beside the point cloud coordinates of the link pairs may be used. Example of such additional information include, but are not limited by, color information—RGB or grayscale, entity identifiers, surface normals, device structure information, other meta data information. In embodiments, such additional information may for example automatically be extracted from the device CAD model which provide structure information on the device e.g. entities separation, naming, allocation etc. In embodiments, a link may be a sub-portion of a link or a super portion of a link.

In embodiments, the ML module may be trained upfront and provided as a trained module to the final users. In other embodiments, the users can do their ML training. The training can be done with the use of the CAR tool and also in the cloud.

In embodiments, the labeled observation data set is divided in a training set, validation set and a test set; the ML algorithm is fed with the training set and the prediction model receives inputs from the machine learner and from the validation set to output the statistics to help tune the training process as it goes and make decisions on when to stop it.

In embodiments, circa 70% of the dataset may be used as training dataset for the calibration of the weights of the neural network, circa 20% of the dataset may be used as validation dataset for control and monitor of the current training process and modify the training process if needed, and circa 10% of the dataset may be used later as test set, after the training and validation is done, for evaluating the accuracy of the ML algorithm.

In embodiments, the entire data preparation for the ML training procedure may be done automatically by a software application.

In embodiments, the output training data are automatically generated from the kinematics object files or from manual kinematics labelling or any combination thereof.

In embodiments, the output training data are provided as metadata, text data, image data and/or any combination thereof.

In embodiments, the input/output training data comprise data in numerical format, in text format, in image format, in other format and/or in any combination thereof.

In embodiments, during the training phase, the ML algorithm learns to detect kinematic joints of the device by “looking” at the point cloud links.

In embodiments, the input training data and the output training data may be generated from a plurality of models of similar or different virtual kinematic devices.

In embodiments, the virtual kinematic devices belong to the same class or belong to a family of classes.

In embodiments, during the training phase with training data, the trained function can adapt to new circumstances and to detect and extrapolate patterns.

In general, parameters of a trained function can be adapted by means of training. In particular, supervised training, semi-supervised training, unsupervised training, reinforcement learning and/or active learning can be used. Furthermore, representation learning (an alternative term is “feature learning”) can be used. In particular, the parameters of the trained functions can be adapted iteratively by several steps of training.

In particular, a trained function can comprise a neural network, a support vector machine, a decision tree and/or a Bayesian network, and/or the trained function can be based on k-means clustering, Qlearning, genetic algorithms and/or association rules.

In particular, a neural network can be a deep neural network, a convolutional neural network, or a convolutional deep neural network. Furthermore, a neural network can be an adversarial network, a deep adversarial network and/or a generative adversarial network.

In embodiments, the ML algorithm is a supervised model, for example a binary classifier which is classifying between true and pseudo error. In embodiments, other classifiers may be used for example logistic regressor, random forest classifier, xgboost classifier etc. In embodiments, a feed forward neural network via TensorFlow framework may be used.

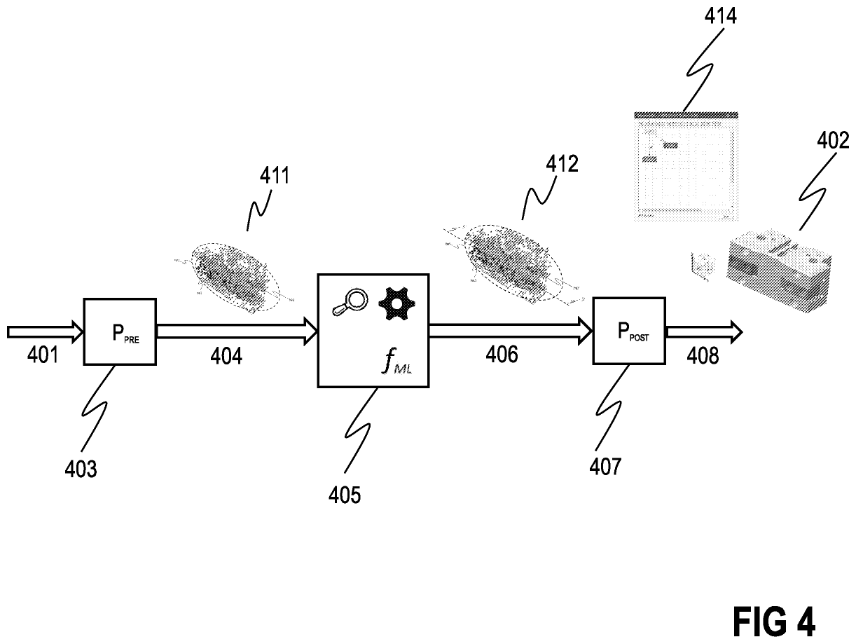

FIG. 4 schematically illustrates a block diagram for determining a joint in a virtual kinematic device in accordance with disclosed embodiments. FIG. 4 schematically shows an example embodiment of neural network execution.

In embodiments, 3D models of link pairs 401 of a virtual gripper are provided. Such 3D model link pairs may be provided in form of a CAD file, mesh file or a 3D scan. In embodiments, the point cloud link pairs 411 are extracted via prep-processing 403. In other embodiments, the point cloud link pairs 411 are received directly without pre-processing 403.

The point cloud point links 411 may contain, in addition to the point coordinates also color or greyscale data for each point, surface normals, entity information and other information.

The input data 404, comprising device point cloud list, is applied to a join descriptor analyzer 405 which provides outputs data 406. The output data comprises joint descriptors which correspond to the input data. The output data 406 are post-processed 407 in order to correct possible alignment issues in the joint descriptors. The information on the determined joint descriptors may be added as kinematic definition to generate a kinematic file (e.g. in a cojt folder) from the departing dummy CAD file (e.g. a .jt file).

In embodiments, the point cloud of a new “unknown” device with same type of joints is applied to the joint descriptor analyzer previously trained with a ML algorithm. The output 406 of the joint descriptor analyzer are joint descriptors for the analyzed cloud link pair 412.

By means of the joint descriptor analyzer, embodiments enable to determine the joint(s) capabilities in order to defining them as part of the kinematic chain(s) of the analyzed device.

Embodiments enable to generate the definition of the kinematics capability of the analyzed device.

In embodiments, during the pre-processing stage 403, the point cloud links 411 entering the system are typically extracted from a CAD/scan model. In embodiments, the origin of the exported point cloud is maintained to be the same as the originating CAD/scan model. Advantageously, the direction of one of the (X, Y, Z) axis may be aligned with a direction of one of the joint. In such cases, during the post processing phase 407, alignment of a determined joint axis descriptor may automatically be performed. For example, if the joint descriptor output unit vector direction is (0, 0.001, 0.999), then this output has a high likelihood to actually be 0,0,1 which implies that a full alignment to the Z axis may be performed. In these cases, the automatic post process can improve the joint descriptor results.

In embodiments, in case of rotational joints, often the axis is in the middle of a cylindrically shaped surface. In embodiments, during the post-processing 407, the determined axis descriptor 406 of a rotational joint may be analyzed with a geometrical analysis tool to determine if the axis is closely surrounded by a cylinder for example by inspecting the normal of the surface around the axis or by analyzing the derivatives of the surface and by adjusting accordingly the joint axis descriptor of the joint to fit the cylinder center.

In other embodiments, during the post-processing 407, the joint descriptor may be adjusted by checking the presence of collisions via simulation and by allowing iterative and/or small adjustments until collisions are avoided or until only collisions with a certain predefined penetration are allowed.

In embodiments, the file of the CAD model can be provided in a jt. format file, e.g. the native format of Process Simulate. In other embodiments, the file describing the device model can be provided into any other suitable file format describing a 3D model or sub-elements of it. In embodiments, this file in this latter format may preferably be converted into JT via a file converter, e.g. an existing one or ad-hoc created converter.

In embodiments, the output 406 of the joint descriptor analyzer 405 algorithm is processed 407 to determine a set of descriptors of the joints for determining the kinematic chain(s) in the device 3D model 402. In embodiments, the generated kinematic chain descriptor data are analyzable via a kinematic editor 414.

In embodiments, the output of the kinematic analyzer with descriptors of the joints 412 is processed by a post-processing module 407. In embodiments, in the post processing module 407 includes determining the kinematic capabilities 408 of the dummy device. In embodiments, the entire kinematic chain(s) can be compiled and created so as to generate an output .jt file with kinematic definitions.

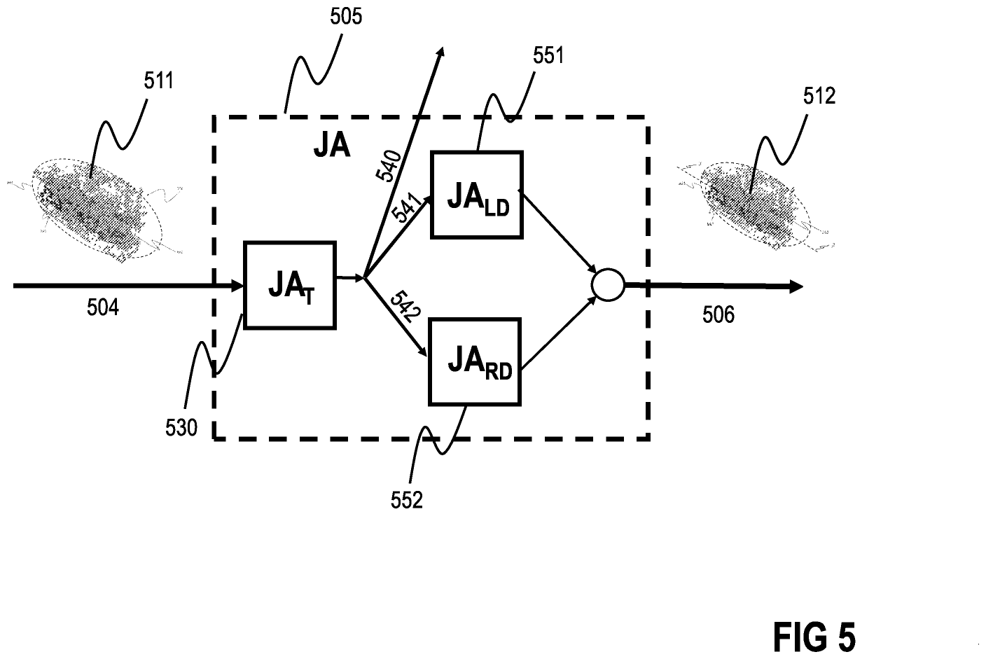

In embodiments, in order to select a suitable joint descriptor analyzer for a given specific joint type, a joint type analyzer may be trained via a ML algorithm and used to analyze the type of joint as explained in FIG. 5 below.

FIG. 5 schematically illustrates a block diagram for identifying a joint in a virtual kinematic device in accordance with disclosed embodiments. FIG. 5 schematically illustrates an example embodiment of executing a cascade of neural network modules 530, 551, 552.

In embodiments, when the joint type is not given, the joint analyzer 505 may be implemented as a cascade of a joint type analyzer JA_{T} and a corresponding joint description analyzer JA_{LD}, JA_{RD} routed according to the outcome of the joint type analyzer JAT.

In embodiments, the input data 504 comprising a point cloud link pair of a given device 511 are applied to the joint analyzer 505 and the outcome data 506 are the type of joint and its corresponding joint descriptors for modeling the kinematic device 512.

Assume simplified exemplary embodiments, where kinematic devices can have either a linear joint or a rotational joint. In this example, three ML modules 530, 551, 552 need to be trained, a joint type analyzer JA_{T} and two specific joint descriptor analyzers, i.e. one linear joint descriptor analyzer JA_{LD} and one rotational joint descriptor analyzer JA_{RD}.

In embodiments, the training/usage of the joint type analyzer module J_{AT} is done with the following data:
input (training) data set: [List of point cloud for link 1, List of point cloud for link 2]
output (training) data set: [joint type: linear or rotational].

In embodiments, the training/usage of the linear joint descriptor analyzer module JA_{LD} is done with the following data:
input (training) data set: [List of point cloud for link 1, List of point cloud for link 2]
output (training) data set: [linear joint descriptor, the moving direction e.g. representable by a unit direction vector (R_{X}, R_{Y}, R_{Z})]

In embodiments, the training/usage of the rotation joint descriptor analyzer module JA_{RD} is done with the following data:
input (training) data set: [List of point cloud for link 1, List of point cloud for link 2]
output (training) data set: [rotational joint descriptor, the rotational central axis e.g. representable by two points or by one direction and one point].

During the usage phase, the three trained modules 530, 551, 552 are used as following:
the joint type analyzer module JA_{T} is used to determine the joint type;
if (the identified joint type is linear 541), then use (linear joint type analyzer module JA_{LD} to determine the linear direction); otherwise;
if (the identified joint type is rotational 542), then use (rotational joint type analyzer module JA_{RD} to determine the rotational axis).

With embodiments, for any new device representable via point cloud links, the joint connecting a pair of links is determined and generated.

In embodiments, the first module 530, joint type analyzer module JA_{T} may preferably be trained via a classification supervised learning algorithm for the different joint types where the outcome is the joint type. In embodiments, the joint type may be no joint 540, linear joint 541 or rotational joint 542. In embodiments, the link pair 504 is determined by selecting two links which are touching, colliding or are close to each other, for example the first link pair comprises links lnk1, lnk2 and the second link pair comprises links lnk1, lnk3.

In embodiments, the second module 551, the linear joint descriptor analyzer module JALD may preferably be trained via a regression supervised learning algorithm for linear joint only where the outcome is the moving linear direction of the joint, which may be described via a unit vector.

In embodiments, the second module 552, the rotational joint descriptor analyzer module JARD may preferably be trained via a regression supervised learning algorithm for rotational joint only where the outcome is the rotational central axis of the joint, which may be described by a unit vector and a location for determining the axis intersection. In embodiments, the intersection is the axis intersection with a known plane, for example the plane which intersects with the origin and is perpendicular to the direction unit vector.

In embodiments, the ranges (max and min values) of the joint descriptors e.g. the maximum and minimum values may be inputted manually or may be extracted from specifications/manuals information.

In the above exemplary embodiments, only two types of joints are analyzed, i.e. linear and rotational joints. In other embodiments, the skilled in the art knows that more joint types may be analyzed, and the classifier may for example be able to output up to six different joint types and up to six different specific joint descriptor analyzers may be trained and used (not shown).

Example of output (training) data descriptors for each of six specific joint descriptor analyzers are reported below: 1) a direction for a linear joint; 2) a direction and location for a rotational joint; 3) a location for a spherical joint representing its center; 4) a direction and location for a cylindrical joint; 5) a direction, location and a scalar helical pitch for a helical joint; 6) a direction (perpendicular to the movement plane) for a planar joint.

In embodiments, a direction of an axis may be defined by a 3D point coordinate of a unit vector direction.

In embodiments, a location may be represented by three coordinates or, for a rotational and cylindrical joint, the intersection of the rotation axis may be determined via a 2D location on the plane perpendicular to the direction unit vector, e.g. where the plane intersects with the general point cloud origin.

In embodiments, the skilled in the art knows that the joint descriptors may also be described in other manners, for example via a 3D angle, or a rotation matrix, or quaternions etc.

It is noted that each type of joint may also be defined as an ensemble of rotational and linear joints.

In embodiments, the classifier which classifies one of the six joint types, may advantageously be followed by a post process module which transforms the received outcome as a combination of linear and revolute joints.; for example, a spherical joint may be transformed to be a combination of three intersecting revolute joints; a cylindrical joint a combination of one revolute joint intersecting one linear joint; an helical joint a combination of one revolute joint and one linear joint with a dependency between the joints: and, a planar joint as a combination of two linear joints and one revolute joint. In embodiments, the joint specific ML module may be trained to recognize the above corresponding specific combination of joint types.

Embodiments have been described for a device like a gripper with three links and two joints. In embodiments, kinematic devices may have any numbers of links and joints. In embodiments, the device might be any device having at least one kinematic capability and chain.

In embodiments, the joint analyzer is a specific device analyzer and is trained and used specifically for a given type of kinematic device, e.g. specifically for certain type(s) of clamps, of grippers or of fixtures.

In other embodiments, the joint analyzer is a general device analyzer and is trained and is used to fit a broad family of different type of kinematic devices.

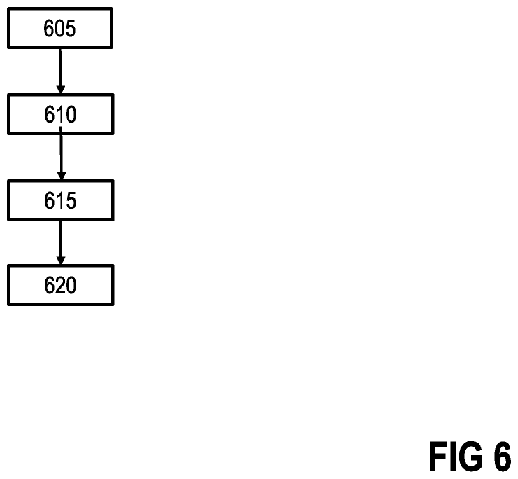

FIG. 6 illustrates a flowchart of a method for determining a joint in a virtual kinematic device in accordance with disclosed embodiments. Such method can be performed, for example, by system 100 of FIG. 1 described above, but the “system” in the process below can be any apparatus configured to perform a process as described. The virtual kinematic device is a virtual device having at least one kinematic capability and wherein a kinematic capability is defined by at least two links of the virtual device and a joint connecting these two links.

At act 605, input data are received. The input data comprise data on two point cloud representations of two given links of a given virtual kinematic device and data on the specific joint type associated to the two links.

At act 610, a specific joint descriptor analyzer is applied to the input data. The specific joint descriptor analyzer is modeled with a function trained by a ML algorithm and the specific joint descriptor analyzer generates output data.

At act 615, the output data is provided. The output data comprises specific joint descriptor data for determining the mutual motion capabilities of the specific joint type associated to the two given links.

At act 620, it is determined, from the output data, at least one joint in the virtual kinematic device.

In embodiments, the joint type may be selected from the group consisting of; linear joint; rotational joint; spherical joint; cylindrical joint; helical joint; and, planar joint.

In embodiments, the joint descriptor data may be selected from the group consisting of one or more of spatial data for defining a direction; spatial data for defining a location; scalar data for defining a helical pitch; spatial data for defining a direction, location and/or helical pitch.

In embodiments, a direction joint descriptor may be used for linear, rotational, helical and planar joints. In embodiments, a direction descriptor may be a unit vector. In embodiments, a location joint descriptor may be used for a rotational, spherical, cylindrical and helical joints.

In embodiments, the data on the point cloud representation include data selected from the group consisting of: coordinates data; color data; entity indentifiers data; surface normals data; data related to the points such as feature data which may be data generated from a computer vision algorithm. or another machine learning model.

In embodiments, the input data are received from a ML module trained to identify two links from a point cloud representation. In embodiments, the joint type is received from a ML module trained to classify the joint type.

In embodiments, the input data are extracted from a 3D model of the virtual kinematic device.

Embodiments further include the step of controlling at least one manufacturing operation performed by a kinematic device in accordance with the outcomes of a computer implemented simulation of a corresponding set of virtual manufacturing operations of a corresponding virtual kinematic device.

In embodiments, at least one manufacturing operation performed by the kinematic device is controlled in accordance with the outcomes of a simulation of a set of manufacturing operations performed by the virtual kinematic device in a virtual environment of a computer simulation platform.

In embodiments, the term “receiving”, as used herein, can include retrieving from storage, receiving from another device or process, receiving via an interaction with a user or otherwise.

Those skilled in the art will recognize that, for simplicity and clarity, the full structure and operation of all data processing systems suitable for use with the present disclosure is not being illustrated or described herein. Instead, only so much of a data processing system as is unique to the present disclosure or necessary for an understanding of the present disclosure is illustrated and described. The remainder of the construction and operation of data processing system 100 may conform to any of the various current implementations and practices known in the art.

It is important to note that while the disclosure includes a description in the context of a fully functional system, those skilled in the art will appreciate that at least portions of the present disclosure are capable of being distributed in the form of instructions contained within a machine-usable, computer-usable, or computer-readable medium in any of a variety of forms, and that the present disclosure applies equally regardless of the particular type of instruction or signal bearing medium or storage medium utilized to actually carry out the distribution. Examples of machine usable/readable or computer usable/readable mediums include: nonvolatile, hard-coded type mediums such as read only memories (ROMs) or erasable, electrically programmable read only memories (EEPROMs), and user-recordable type mediums such as floppy disks, hard disk drives and compact disk read only memories (CD-ROMs) or digital versatile disks (DVDs).

Although an exemplary embodiment of the present disclosure has been described in detail, those skilled in the art will understand that various changes, substitutions, variations, and improvements disclosed herein may be made without departing from the spirit and scope of the disclosure in its broadest form.

None of the description in the present application should be read as implying that any particular clement, step. or function is an essential element which must be included in the claim scope: the scope of patented subject matter is defined only by the allowed claims.

1-18. (canceled)

19. A method for determining, by a data processing system, a joint in a virtual kinematic device, the virtual kinematic device being a virtual device having at least one kinematic capability that is defined by at least two links of the virtual device and a joint connecting the two links, and the joint being defined by a joint type and by a joint descriptor for defining motion capabilities of a specific joint type; the method comprising:
receiving input data containing data on two point cloud representations of two given links of a given virtual kinematic device;
applying a joint type analyzer to the input data, the joint type analyzer being modeled with a function trained by a machine learning (ML) algorithm and the joint type analyzer generating intermediate data;
providing the intermediate data containing data for selecting a specific joint type associated with the two given links;
applying the selected specific joint descriptor analyzer to the input data, the specific joint descriptor analyzer being modeled with a function trained by a ML algorithm and the specific joint descriptor analyzer generating output data;
providing the output data containing specific joint descriptor data for determining the mutual motion capabilities of the specific joint type associated with the two given links; and
determining from the output data at least one joint in the virtual kinematic device.

20. The method according to claim 19, wherein the joint type is selected from the group consisting of:
a linear joint;
a rotational joint;
a spherical joint;
a cylindrical joint;
a helical joint; and
a planar joint.

21. The method according to claim 19, wherein the joint descriptor data is one or more selected from the group consisting of:
spatial data for defining a direction;
spatial data for defining a location;
scalar data for defining a helical pitch; and
spatial data for defining a direction, location and/or helical pitch.

22. The method according to claim 19, wherein the data on the point cloud representation include data selected from the group consisting of:
coordinates data;
color data;
entity identifiers data;
surface normals data; and
other features extracted from a computer vision technique or from another machine learning (ML) module.

23. The method according to claim 19, which comprises receiving the input data from a ML module trained to identify two links from a point cloud representation.

24. The method according to claim 19, which comprises extracting the input data from a 3D model of the virtual kinematic device.

25. The method according to claim 19, which further comprises controlling at least one manufacturing operation performed by a kinematic device in accordance with outcomes of a computer-implemented simulation of a corresponding set of virtual manufacturing operations of a corresponding virtual kinematic device.

26. A method for determining, by a data processing system, a joint in a virtual kinematic device, the virtual kinematic device being a virtual device having at least one kinematic capability that is defined by at least two links of the virtual device and a joint connecting the two links, and the joint being defined by a joint type and by a joint descriptor for defining motion capabilities of a specific joint type; the method comprising:
receiving input data containing data on two point cloud representations of two given links of a given virtual kinematic device and data on the specific joint type associated with the two links;
applying a specific joint descriptor analyzer to the input data, the specific joint descriptor analyzer being modeled with a function trained by a machine learning (ML) algorithm, and the specific joint descriptor analyzer generating output data;
providing the output data containing specific joint descriptor data for determining the mutual motion capabilities of the specific joint type associated with the two given links; and
determining from the output data at least one joint in the virtual kinematic device.

27. The method according to claim 26, wherein the joint type is selected from the group consisting of:
a linear joint;
a rotational joint;
a spherical joint;
a cylindrical joint;
a helical joint; and
a planar joint.

28. The method according to claim 26, wherein the joint descriptor data is one or more selected from the group consisting of:
spatial data for defining a direction;
spatial data for defining a location;
scalar data for defining a helical pitch; and
spatial data for defining a direction, location and/or helical pitch.

29. The method according to claim 26, wherein the data on the point cloud representation include data selected from the group consisting of:
coordinates data;
color data;
entity identifiers data;
surface normals data; and
other features extracted from a computer vision technique or from another ML module.

30. The method according to claim 26, which comprises receiving the input data from a ML module trained to identify two links from a point cloud representation.

31. The method according to claim 26, which comprises extracting the input data from a 3D model of the virtual kinematic device.

32. The method according to claim 26, which further comprises controlling at least one manufacturing operation performed by a kinematic device in accordance with outcomes of a computer-implemented simulation of a corresponding set of virtual manufacturing operations of a corresponding virtual kinematic device.

33. A method for providing, by a data processing system, a trained function for identifying a joint type in a virtual kinematic device, the virtual kinematic device being a virtual device having at least one kinematic capability and the kinematic capability being defined by at least two links of the virtual device and a joint connecting the two links, and the joint being defined by a joint type and by a joint descriptor for defining motion capabilities of a specific joint type; the method comprising:
receiving input training data containing data on a plurality of two point cloud representations of two given links of a plurality of virtual kinematic devices;
receiving output training data containing, for each of the plurality of two point cloud link representations, data for determining a specific joint type associated with the two given links, the output training data being related to the input training data;
training a function based on the input training data and the output training data via a machine learning (ML) algorithm; and
providing the training function for modeling a joint type analyzer.

34. The method according to claim 33, wherein the joint type is selected from the group consisting of:
a linear joint;
a rotational joint;
a spherical joint;
a cylindrical joint;
a helical joint; and
a planar joint.

35. The method according to claim 34, wherein the joint descriptor data is one or more selected from the group consisting of:
spatial data for defining a direction;
spatial data for defining a location;
scalar data for defining a helical pitch; and
spatial data for defining at least one of a direction, location, or helical pitch.

36. A method for providing, by a data processing system, a trained function for identifying a joint descriptor in a virtual kinematic device, the virtual kinematic device being a virtual device having at least one kinematic capability and the kinematic capability being defined by at least two links of the virtual device and a joint connecting the two links, and the joint being defined by a joint type and by a joint descriptor for defining motion capabilities of a specific joint type; the method comprising:
receiving input training data containing data on a plurality of two point cloud representations of two given links of a plurality of virtual kinematic devices;
receiving output training data containing, for each of the plurality of two point cloud link representations, specific joint descriptor data for determining mutual motion capabilities of the specific joint type associated with the two given links;
training a function based on the input training data and the output training data via a machine learning (ML) algorithm; and
providing the trained function for identifying a joint descriptor being a joint descriptor analyzer.

37. The method according to claim 36, wherein the joint type is selected from the group consisting of:
a linear joint;
a rotational joint;
a spherical joint;
a cylindrical joint;
a helical joint; and
a planar joint.

38. The method according to claim 37, wherein the joint descriptor data is one or more selected from the group consisting of:
spatial data for defining a direction;
spatial data for defining a location;
scalar data for defining a helical pitch; and
spatial data for defining at least one of a direction, a location, or helical pitch.

39. A data processing system, comprising:
a processor; and
an accessible memory, the data processing system being configured to:
receive input data containing data on two point cloud representations of two given links of a given virtual kinematic device and data on a specific joint type associated with the two given links;
apply a specific joint descriptor analyzer to the input data, the specific joint descriptor analyzer being modeled with a function trained by a machine learning (ML) algorithm and the specific joint descriptor analyzer generating output data;
provide the output data containing specific joint descriptor data for determining mutual motion capabilities of the specific joint type associated with the two given links; and
determine from the output data at least one joint in the virtual kinematic device.

40. A non-transitory computer-readable medium with computer-executable instructions that, when executed by the data processing system according to claim 39, cause the data processing system to:
receive the input data containing the data on the two point cloud representations of two given links of the given virtual kinematic device and data on the specific joint type associated with the two given links;
apply the specific joint descriptor analyzer to the input data, the specific joint descriptor analyzer being modeled with a function trained by a machine learning (ML) algorithm and the specific joint descriptor analyzer being configured to generate output data,
provide the output data containing specific joint descriptor data for determining mutual motion capabilities of the specific joint type associated with the two given links; and
determine from the output data at least one joint in the virtual kinematic device.

41. A data processing system, comprising:
a processor; and
an accessible memory, the data processing system being configured to:
receive input training data, the input data containing data on a plurality of two point cloud representations of two given links of a plurality of virtual kinematic devices;
receive output training data related to the input training data, the output training data containing, for each of the plurality of two point cloud link representations, data for determining a specific joint type associated with the two given links;
train a function based on the input training data and the output training data via a machine learning (ML) algorithm to form a training function; and
provide the training function for modeling a joint type analyzer.

42. A non-transitory computer-readable medium with computer-executable instructions that, when executed by the data processing system according to claim 41, cause the data processing system to:
receive the input training data containing the data on the plurality of two point cloud representations of the two given links of the plurality of virtual kinematic devices;
receive the output training data related to the input training data, the output training data containing, for each of the plurality of two point cloud link representations, data for determining a specific joint type associated with the two given links;
train a function based on the input training data and the output training data via a machine learning (ML) algorithm to form a trained function; and
provide the trained function for modeling a joint type analyzer.

43. A data processing system, comprising:
a processor; and
an accessible memory, the data processing system being configured to:
receive input training data, the input training data containing data on a plurality of two point cloud representations of two given links of a plurality of virtual kinematic devices;
receive output training data, the output training data containing, for each of the plurality of two point cloud link representations, specific joint descriptor data for determining the mutual motion capabilities of a specific joint type associated with the two given links;
train a function based on the input training data and the output training data via a machine learning (ML) algorithm to form a trained function; and
provide the trained function for modeling a joint descriptor analyzer.

44. A non-transitory computer-readable medium with computer-executable instructions that, when executed by the data processing system according to claim 43, cause the data processing system to:
receive input training data with data on a plurality of two point cloud link representations of the two given links of the plurality of virtual kinematic devices;
receive output training data containing, for each of the plurality of two point cloud link representations, the specific joint descriptor data for determining the mutual motion capabilities of the specific joint type associated with the two given links;
train a function based on the input training data and the output training data via a machine learning (ML) algorithm to form a trained function; and
provide the trained function for modeling a joint descriptor analyzer.
